(19) United States
(12) Patent Application Publication
(10) Pub. No.: US 2012/0309171 A1
(43) Pub. Date: Dec. 6, 2012

(54) METHOD FOR FABRICATING SEMICONDUCTOR DEVICE

(76) Inventors: Tsuo-Wen Lu, Kaohsiung City (TW); Wen-Yi Teng, Kaohsiung City (TW); Yu-Ren Wang, Tainan City (TW); Gin-Chen Huang, New Taipei City (TW); Chien-Liang Lin, Taoyuan County (TW); Shao-Wei Wang, Taichung City (TW); Ying-Wei Yen, Miaoli County (TW); Ya-Chi Cheng, Kaohsiung City (TW); Shu-Yen Chan, Hsinchu County (TW); Chan-Lon Yang, Taipei City (TW)

(21) Appl. No.: 13/118,473

(22) Filed: May 30, 2011

(51) Int. Cl. H01L 21/20

(52) U.S. Cl. 438/478; 438/595; 257/E21.09

(57) ABSTRACT

A method for fabricating semiconductor device is disclosed. The method includes the steps of: providing a substrate, wherein the substrate comprises a gate structure thereon; forming a film stack on the substrate and covering the gate structure, wherein the film stack comprises at least an oxide layer and a nitride layer; removing a portion of the film stack for forming recesses adjacent to two sides of the gate structure and a disposable spacer on the sidewall of the gate structure; and filling the recesses with a material comprising silicon atoms for forming a faceted material layer.

### BACKGROUND OF THE INVENTION

1. Field of the Invention

The invention relates to a method for fabricating semiconductor device, and more particularly, to a method for fabricating metal-oxide semiconductor transistor.

2. Description of the Prior Art

A conventional MOS transistor generally includes a semiconductor substrate, such as silicon, a source region, a drain region, a channel positioned between the source region and the drain region, and a gate located above the channel. The gate is composed of a gate dielectric layer, a gate conductive layer positioned on the gate dielectric layer, and a plurality of spacers positioned on the sidewalls of the gate conductive layer. Generally, for a given electric field across the channel of a MOS transistor, the amount of current that flows through the channel is directly proportional to a mobility of the carriers in the channel. Therefore, how to improve the carrier mobility so as to increase the speed performance of MOS transistors has become a major topic for study in the semiconductor field.

The formation of SiGe source/drain regions is commonly achieved by epitaxially growing a SiGe layer adjacent to the spacers within the semiconductor substrate after forming the spacer. In this type of MOS transistor, a biaxial tensile strain occurs in the epitaxial silicon layer due to the silicon germanium, which has a larger lattice constant than silicon, and, as a result, the band structure alters, and the carrier mobility increases. This enhances the speed performance of the MOS transistor.

However, it should be noted in the conventional art for conducting selective epitaxial growth process to form epitaxial layer, the epitaxial layer is typically grown against the sidewall of the spacer. This type of growing behavior often causes reduced strain in the channel region of the transistor and induces a Ion degradation phenomenon. As a result, the performance of the device is affected substantially.

### SUMMARY OF THE INVENTION

It is an objective of the present invention to provide a method for fabricating semiconductor transistor for resolving the aforementioned issue.

According to a preferred embodiment of the present invention, a method for fabricating semiconductor device is disclosed. The method includes the steps of: providing a substrate, wherein the substrate comprises a gate structure thereon; forming a film stack on the substrate and covering the gate structure, wherein the film stack comprises at least an oxide layer and a nitride layer; removing a portion of the film stack for forming recesses adjacent to two sides of the gate structure and a disposable spacer on the sidewall of the gate structure; and filling the recesses with a material comprising silicon atoms for forming a faceted material layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating semiconductor device according to a first embodiment of the present invention.

### DETAILED DESCRIPTION

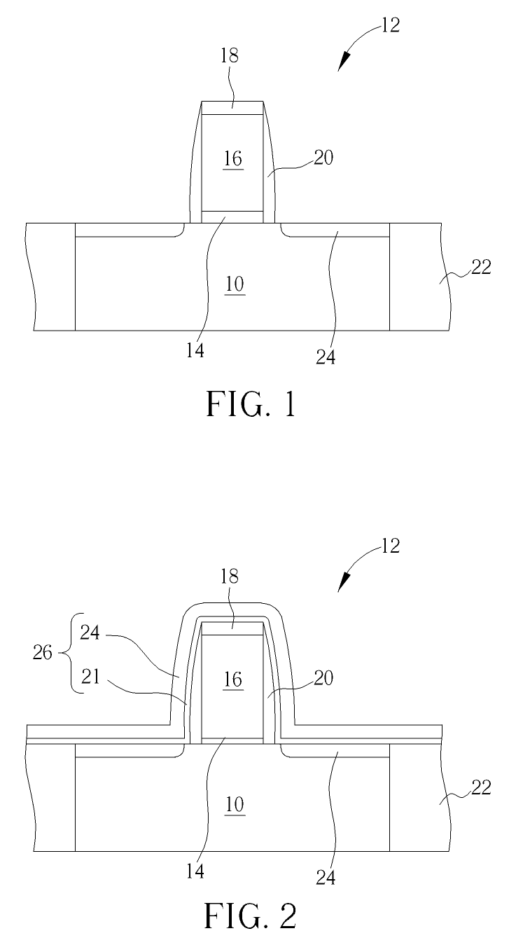

Referring to FIGS. 1-6, FIGS. 1-6 illustrate a method for fabricating a semiconductor device according to a first embodiment of the present invention. As shown in FIG. 1, a substrate 10, such as a silicon wafer or a silicon-on-insulator substrate is provided. A gate structure 12 is disposed on the substrate 10, and the active region for which the gate structure 12 resides in is surrounded by a shallow trench isolation 22. The gate structure 12 includes a gate dielectric layer 14, a gate 16 disposed on the gate dielectric layer 14, and a cap layer 18 disposed on top of the gate 16. The gate dielectric layer 14 may be composed of a single layer of insulating material such as silicon oxides, silicon nitrides, high-k dielectric material, or combination thereof, the gate 16 is composed of conductive materials such as doped or undoped single crystal silicon or polysilicon, silicon germanium, silicides, or other metals, and the cap layer 18 is composed of dielectric material such as silicon nitride or silicon oxide.

Next, an offset spacer 20 is formed on the sidewall of the gate structure 12, in which the offset spacer 20 is composed of material such as silicon nitride. An ion implantation is then conducted by using the gate structure 12 and the offset spacer 20 as a mask to implant p-type or n-type dopants into the substrate 10 adjacent to two sides of the offset spacer 20. This ion implantation preferably forms a lightly doped drain 24 at two sides of the gate structure 12.

Next, as shown in FIG. 2, a chemical vapor deposition is conducted to form a film stack 26 compose of an oxide layer 22 and a nitride layer 24 on the surface of the substrate, 10, the offset spacer 20, and the gate structure 12. In this embodiment, the nitride layer 24 of film stack 26 is preferably formed with at least a precursor containing chlorine atoms, such as hexachlorosilane (HCD), in which the fabricated oxide layer 22 has a thickness between 10-50 Angstroms, such as preferably at about 30 Angstroms while the nitride layer 24 has a thickness of between 60-180 Angstroms, such as preferably at about 120 Angstroms. However, instead of using hexachlorosilane as the precursor for forming the film stack 26, other precursors that contain chlorine such as dichlorosilane or those do not contain chlorine atoms could also be used for forming the nitride layer 24, which is also within the scope of the present invention.

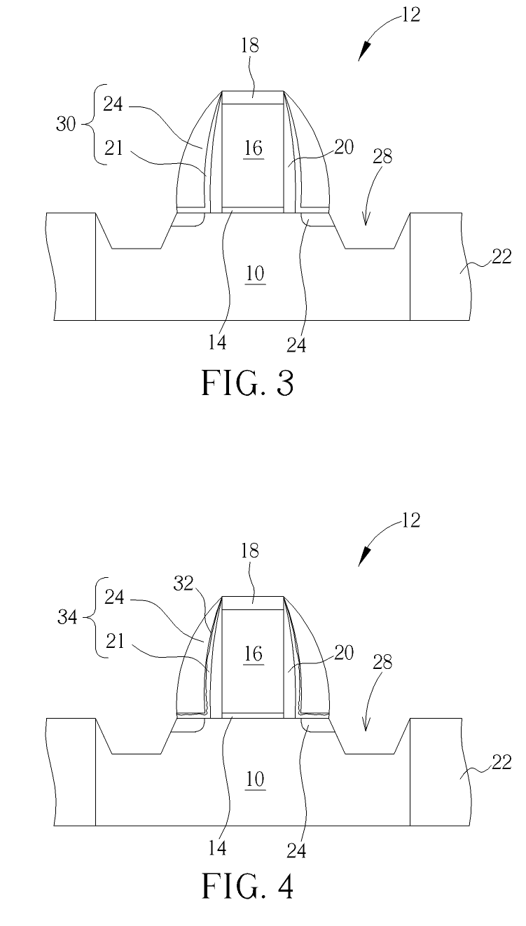

Next, as shown in FIG. 3, one or more etching processes, such as a dry etching process, a wet etching process, or both to partially remove the oxide layer 22 and the nitride layer 24 are conducted. This preferably forms two recesses 28 in the substrate 10 adjacent to two sides of the gate structure 12 and a disposable spacer 30 composed of an L-shaped oxide layer 22 and the remaining nitride layer 24 on the sidewall of the gate structure 12 simultaneously.

In addition to the above approach for forming the disposable spacer 30, another embodiment of present invention could first deposit an oxide layer 22 between 30-70 Angstroms, such as preferably at 50 Angstroms on the substrate 10, the offset spacer 20, and the gate structure 12, as shown in FIG. 4, and a treatment, such as a decoupled plasma nitridation (DPN) process is carried out on the deposited oxide layer 22 to form nitrogen-containing substance 32 in the oxide layer 22. Next, a nitride layer 24 between 50-150 Angstroms, such as preferably at about 100 Angstroms is deposited on the oxide layer 22 having nitrogen-containing substance 32, and the aforementioned dry etching and/or wet etching process is conducted to partially remove the oxide layer 22 and the nitride layer 24 for forming two recesses 28 in the substrate 10 adjacent to two sides of the gate structure 12 and a disposable spacer 34 on the sidewall of the gate structure 12.

It should be noted that despite a DPN process is conducted to inject nitrogen-containing substance 32 between the oxide layer 22 and the nitride layer 24 in the above embodiment, a rapid thermal anneal process or a furnace anneal process could also be performed on the oxide layer 22 in a nitrogen-containing environment for forming the oxide layer 22 having nitrogen-containing substance 32, which is also within the scope of the present invention.

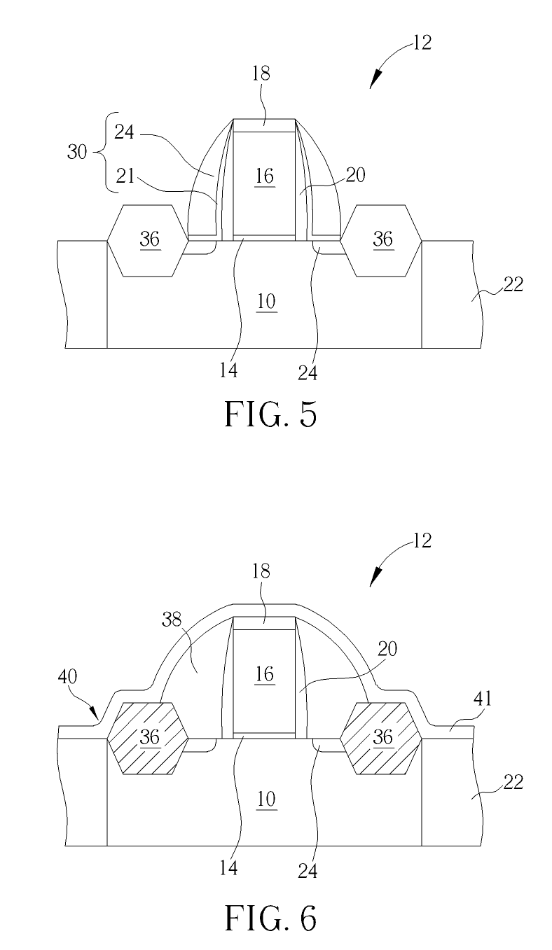

Next, as shown in FIG. 5, a pre-clean process is performed by using diluted hydrofluoric acid or SPM solution containing sulfuric acid, hydrogen peroxide, and deionized water to remove native oxides or other impurities from the surface of the recesses 28, and then filling the recesses 28 with a material layer containing silicon atoms for forming an epitaxial layer 36. In this embodiment, a selective strain scheme (SSS), such as a selective epitaxial growth (SEG) process may be employed to form the epitaxial layer 36, in which the epitaxial layer 36 could include a SiGe layer or a SiC layer.

In contrast to the conventional selective epitaxial growth process of growing the epitaxial layer right along the spacer composed of silicon nitride, the disposable spacer of the present invention is preferably composed of an L-shaped oxide layer and a nitride layer disposed on the L-shaped oxide layer. As the L-shaped oxide layer is adhered to the surface of the substrate and immediately adjacent to the source/drain region, the present invention could prevent the epitaxial layer to grow against the sidewall of the disposable spacer. Instead, a gap is formed between the epitaxial layer and the sidewall of the disposable spacer, and a faceted epitaxial layer, such as a hexagonal epitaxial layer is formed in the substrate. It should be noted that the faceted feature is preferably demonstrated in the portion of the epitaxial layer 36 above the substrate 10, such that the angle of the epitaxial layer 36 is preferably around 15-60 degrees. For instance, the angle included between the (111) face of the epitaxial layer and the (100) face of the substrate is about 54.74 degrees and the angle included between the (113) face of the epitaxial layer and the (100) face of the substrate is about 25.24 degrees. The entire shape of epitaxial layer 36 however is not limited to hexagonal. Instead, the parameter of the etching process carried out to form the recess 28 in the substrate 10 could be used to determine the shape of the epitaxial layer 36.

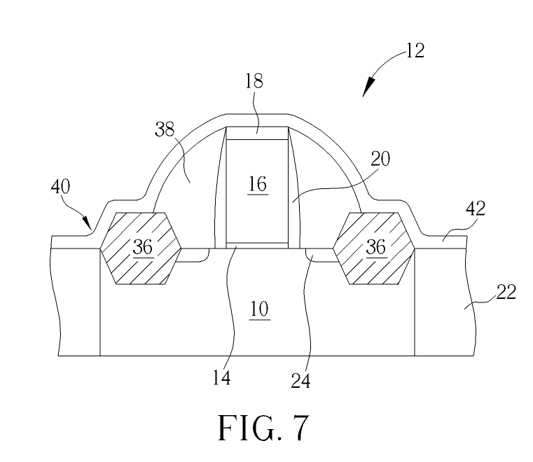

Next, as shown in FIG. 6, the disposable spacer 30 could be selectively removed according to the demand of the product to leave only the offset spacer 20 on the sidewall of the gate structure 12. Thereafter, a main spacer 38 could be found around the offset spacer 20 and an ion implant could be carried out to form a source/drain region 40 in the substrate 10 adjacent to two sides of the main spacer 38. A stress memorization technology (SMT) could then be performed to first perform an ion implant to amorphize the exposed silicon material and then form a stress transfer structure (not shown), such as silicon nitride layer containing stress on the surface of the gate structure 12 and the substrate 10, and an anneal process is conducted to remove the stress transfer structure for increasing the ion performance of the device. In this embodiment, the stress transfer structure could either be a tensile stress layer or a compressive stress layer.

Similar to the aforementioned embodiment of using selective strain scheme for forming epitaxial layer, if the transistor fabricated is an NMOS transistor, a tensile stress layer could be formed on the gate structure and the substrate for carrying out the stress memorization technology. However, if the transistor fabricated is a PMOS transistor, a compressive stress layer could be formed on the gate structure and the substrate for carrying out the stress memorization technology. As the process of stress memorization technology is well known to those skilled in the art, the details of which are omitted herein for the sake of brevity.

Next, a salicide process is performed by sputtering a metal layer (not shown) composed of cobalt, titanium, platinum, palladium, or molybdenum on the epitaxial layer and conducting at least one rapid thermal anneal process to react the metal layer and the epitaxial layer for forming a silicide layer (not shown). A contact etch stop layer (CESL) and an interlayer dielectric layer could then be deposited on the substrate 10. As the process for fabricating these elements are well known to those skilled in the art, the details of which are omitted herein for the sake of brevity.

It should be noted that despite the disposable spacer 30 is removed before the formation of the stress transfer structure, the disposable spacer 30 could also be removed before the formation of the CESL, which is also within the scope of the present invention.

Overall, the present invention preferably forms a film stack composed of an oxide layer and a nitride layer on the substrate and the gate structure, such that during the formation of epitaxial layer, the epitaxial layer contacting the oxide layer would not grow along the sidewall of the disposable spacer. Instead, a gap is formed between the epitaxial layer and the disposable spacer and a faceted hexagonal source/drain region is formed. After removing a portion of the film stack, two recesses are formed in the substrate adjacent to two sides of the gate structure and a disposable spacer is formed on the sidewall of the gate structure.

Moreover, as the dry etching and wet etching process conducted for forming the recesses of the epitaxial layer typically damage the oxide material of the disposable spacer, another embodiment of the present invention preferably conducts a decoupled plasma nitridation process to form nitrogen-containing substance in the oxide layer, which could then be used to protect the oxide layer from damage caused by the subsequent etching processes.

Those skilled in the art will readily observe that numerous modifications and alterations of the device and method may be made while retaining the teachings of the invention.

1. A method for fabricating semiconductor device, comprising:
providing a substrate, wherein the substrate comprises a gate structure thereon;
forming a film stack on the substrate and covering the gate structure, wherein the film stack comprises at least an oxide layer and a nitride layer, wherein the oxide layer comprises a thickness between 30 to 70 Angstroms;
removing a portion of the film stack for forming recesses adjacent to two sides of the gate structure and forming a disposable spacer on a sidewall of the gate structure; and
filling the recesses with a material comprising silicon atoms for forming a faceted material layer.

2. The method of claim 1, wherein the gate structure comprises a gate dielectric layer and a gate.

3. The method of claim 1, further comprising forming an offset spacer or a pad oxide layer on the sidewall of the gate structure before forming the film stack.

4. The method of claim 1, further comprising performing a treatment for forming nitrogen-contained substance between the oxide layer and the nitride layer.

5. The method of claim 4, wherein the treatment comprises a decoupled plasma nitridation process.

6. The method of claim 4, wherein the treatment comprises a rapid thermal anneal process.

7. The method of claim 4, wherein the treatment comprises a furnace anneal process.

8. The method of claim 1, further comprising forming the nitride layer with a precursor containing chlorine atoms.

9. The method of claim 1, further comprising performing a pre-clean after forming the disposable spacer and before forming the faceted material layer.

10. The method of claim 1, further comprising performing a selective epitaxial growth process for forming the faceted material layer.

11. The method of claim 1, wherein the faceted material layer comprises silicon germanium.

12. The method of claim 1, wherein the faceted material layer comprises silicon carbide.

13. The method of claim 1, further comprising performing a stress memorization technology after forming the disposable spacer.

14. The method of claim 1, further comprising forming a contact etch stop layer on the substrate and the gate structure after forming the disposable spacer.

15. The method of claim 1, wherein after forming the disposable spacer further comprises:
performing a stress memorization technology; and
forming a contact etch stop layer on the substrate and the gate structure.

16. The method of claim 1, further comprising removing the disposable spacer after forming the faceted material layer.
